(19) United States
(12) Patent Application Publication
(10) Pub. No.: US 2011/0248343 A1
(43) Pub. Date: Oct. 13, 2011

(54) Schottky FET With All Metal Gate

(75) Inventors: Dechao Guo, Wappingers Falls, NY (US); Marwan Khater, Astoria, NY (US); Christian Lavoie, Pleasantville, NY (US); Qiqing Ouyang, Yorktown Heights, NY (US); Zhen Zhang, Ossining, NY (US)

(73) Assignee: INTERNATIONAL BUSINESS MACHINES CORPORATION, Armonk, NY (US)

(21) Appl. No.: 12/755,720

(22) Filed: Apr. 7, 2010

(51) Int. Cl. H01L 29/78; H01L 21/336

(52) U.S. Cl. 257/347; 438/151; 257/E29.255

(57) ABSTRACT

A method for forming a Schottky field effect transistor (FET) includes forming a gate stack on a silicon substrate, the gate stack comprising a gate polysilicon on top of a gate metal layer; depositing a metal layer over the gate polysilicon and the silicon substrate; annealing the metal layer, the gate polysilicon, and the silicon substrate such that the metal layer fully consumes the gate polysilicon to form a gate silicide and reacts with portions of the silicon substrate to form source/drain silicide regions in the silicon substrate; and in the event a portion of the metal layer does not react with the gate polysilicon or the silicon substrate, removing the unreacted portion of the metal layer.

### FIELD

This disclosure relates generally to the field of Schottky field effect transistor (FET) fabrication.

### DESCRIPTION OF RELATED ART

A Schottky junction source/drain metal-oxide-semiconductor (MOS) field effect transistor (FET) is a viable option for thin-body devices and sub-30 nm gate CMOS technology Schottky FETs may have relatively low parasitic resistance and gate-to-drain parasitic capacitance, due to the lack of raised source/drain regions, as well as abrupt source/drain junctions.

A Schottky FET comprises a gate stack, which may comprise a layer of silicide at the top, a layer of polysilicon, a layer of a metal gate, and a layer of a high-k material at the bottom. The gate metal layer may comprise titanium nitride (TiN) or TaN and may be less than 10 nanometers (nm) thick, and the polysilicon layer may be in the tens of nm thick for spacer formation. The silicide acts to enhance the conductivity of the gate metal. However, the polysilicon layer needs to be doped to sufficiently lower the overall gate stack resistance, requiring extra steps such as gate implantation and activation; these extra steps may require a relatively high processing temperature, which may affect the stability of the layers and materials comprising the FET.

### SUMMARY

In one aspect, a method for forming a Schottky field effect transistor (FET) includes forming a gate stack on a silicon substrate, the gate stack comprising a gate polysilicon on top of a gate metal layer; depositing a metal layer over the gate polysilicon and the silicon substrate; annealing the metal layer, the gate polysilicon, and the silicon substrate such that the metal layer fully consumes the gate polysilicon to form a gate silicide and reacts with portions of the silicon substrate to form source/drain silicide regions in the silicon substrate; and in the event a portion of the metal layer does not react with the gate polysilicon or the silicon substrate, removing the unreacted portion of the metal layer.

In one aspect, a Schottky field effect transistor (FET) includes a silicon substrate; source/drain silicide regions located in the silicon substrate; a gate stack located on the silicon substrate, the gate stack comprising: a high-k material layer located on the silicon substrate; a gate metal layer located on the high-k material layer; and a gate silicide located on the gate metal layer; and a gate interface layer located between the gate silicide and the gate metal layer, and source/drain interface layers located between the source/drain silicide regions and the silicon substrate.

Additional features are realized through the techniques of the present exemplary embodiment. Other embodiments are described in detail herein and are considered a part of what is claimed. For a better understanding of the features of the exemplary embodiment, refer to the description and to the drawings.

### BRIEF DESCRIPTION OF THE SEVERAL VIEWS OF THE DRAWINGS

Referring now to the drawings wherein like elements are numbered alike in the several FIGURES:

FIG. 1 illustrates an embodiment of a method of forming Schottky FET having an all metal gate.

FIG. 2 illustrates an embodiment of a device comprising gate stack and spacers formed on a substrate.

FIG. 3 illustrates an embodiment of the device of FIG. 2 after depositing a metal layer.

FIG. 4 illustrates an embodiment of the device of FIG. 3 after annealing.

FIG. 5 illustrates an embodiment of the device of FIG. 4 after formation of gate and source/drain silicide.

FIG. 6 illustrates an embodiment of implantation of dopants into the device of FIG. 5.

FIG. 7 shows an embodiment of a Schottky FET having an all metal gate and a segregated interfacial layer between the S/D silicide and the Si channel.

### DETAILED DESCRIPTION

Embodiments of a Schottky FET having an all metal gate and methods of making a Schottky FET having an all metal gate are provided, with exemplary embodiments being discussed below in detail. The FET all metal gate stack may comprise a gate metal layer (such as TiN) and a silicide layer, with no polysilicon layer. The gate metal thickness may be relatively thick to allow spacer formation. The gate polysilicon and source/drain silicon may be silicided simultaneously, and the gate silicide may have approximately the same thickness as the source/drain silicide. The process may be relatively low temperature, and no gate implantation and activation are needed.

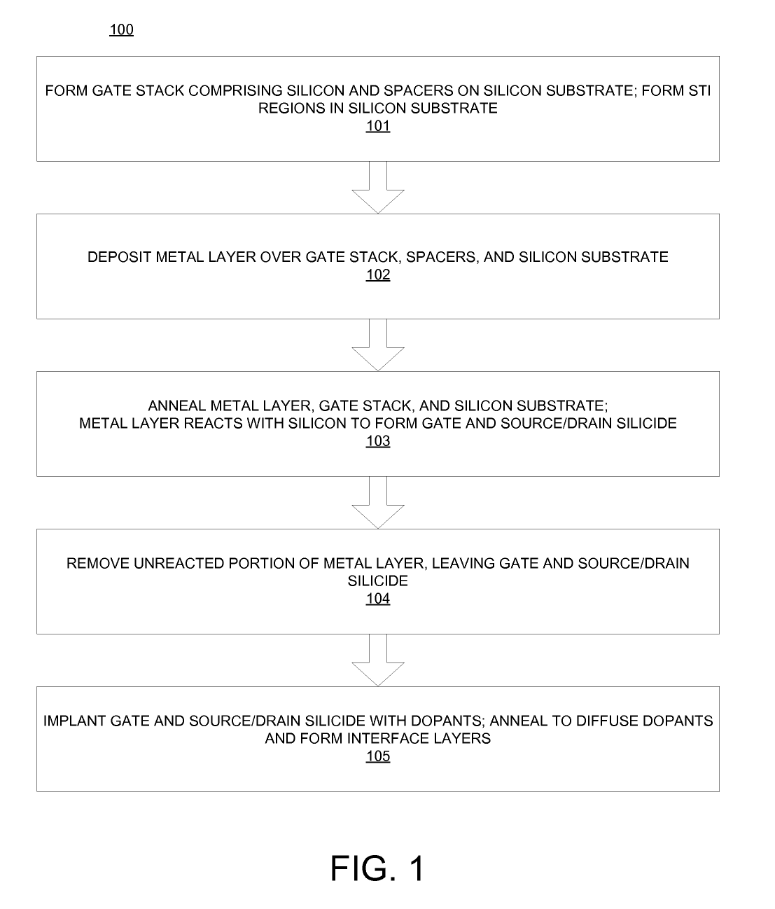

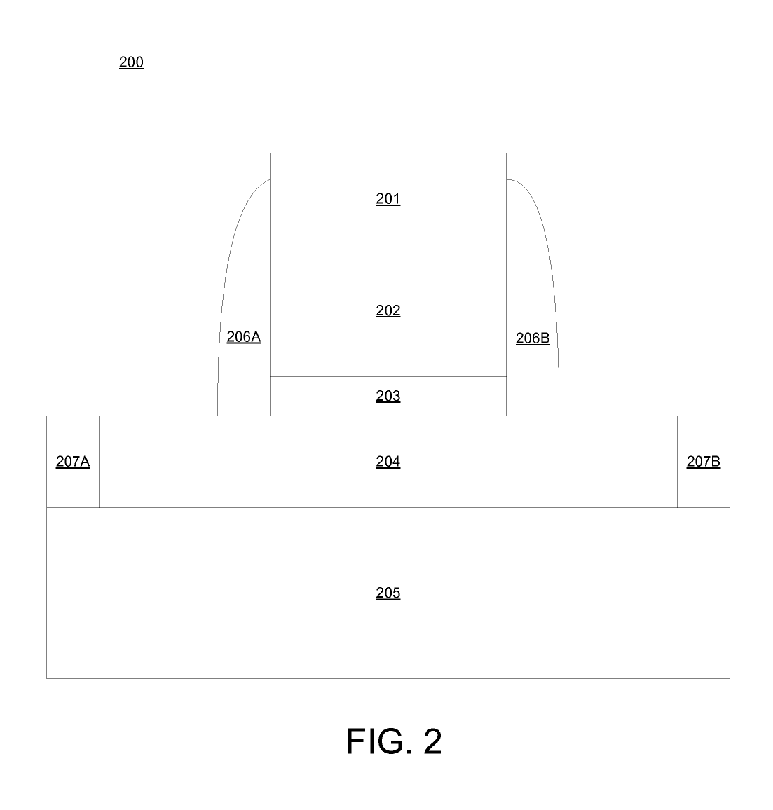

FIG. 1 illustrates a method 100 of forming a FET having a FUSI gate. FIG. 1 is discussed with reference to FIGS. 2-5. In block 101, Shallow trench isolation (STI) regions 207A-B are also formed in silicon substrate 204, and a gate stack is formed on a silicon substrate 204, as is shown in FIG. 2. The gate stack comprises polysilicon layer 201, gate metal layer 202, and high-k material layer 203. Polysilicon layer 201 and silicon substrate 204 may have approximately the same thickness. Gate metal layer 202 may comprise TiN or tantalum nitride (TaN) in some embodiments, and may be greater than about 10 nm thick. Silicon substrate 204 is located over insulator layer 205, which may comprise oxide. Silicon substrate may comprise extremely thin silicon on insulator (ETSOI), and may be 10 nm thick or less in some embodiments. After formation of the gate stack, spacers 206A-B are formed adjacent to the gate stack. Spacers 206A-B may comprise nitride in some embodiments, and may be 10 nm thick or less in some embodiments.

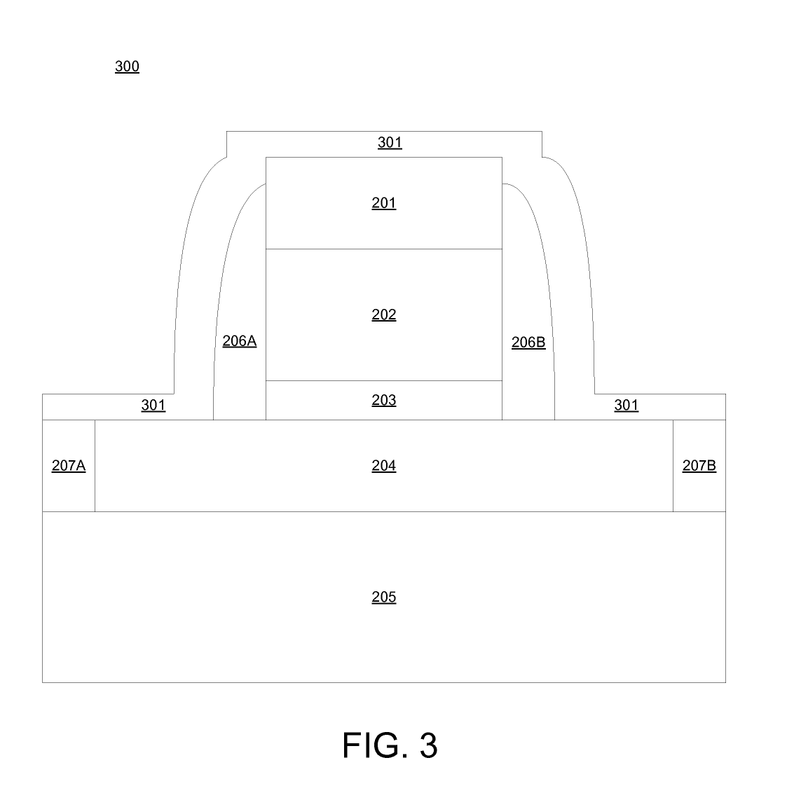

In block 102, a metal layer 301 is deposited on polysilicon layer 201, spacers 206A-B, and the exposed portion of silicon substrate 204, as is shown in FIG. 3. Metal layer 301 may comprise nickel (Ni) or nickel platinum (NiPt) in some embodiments. The thickness of metal layer 301 may be determined by the thickness of polysilicon layer 201, as discussed below with respect to block 103.

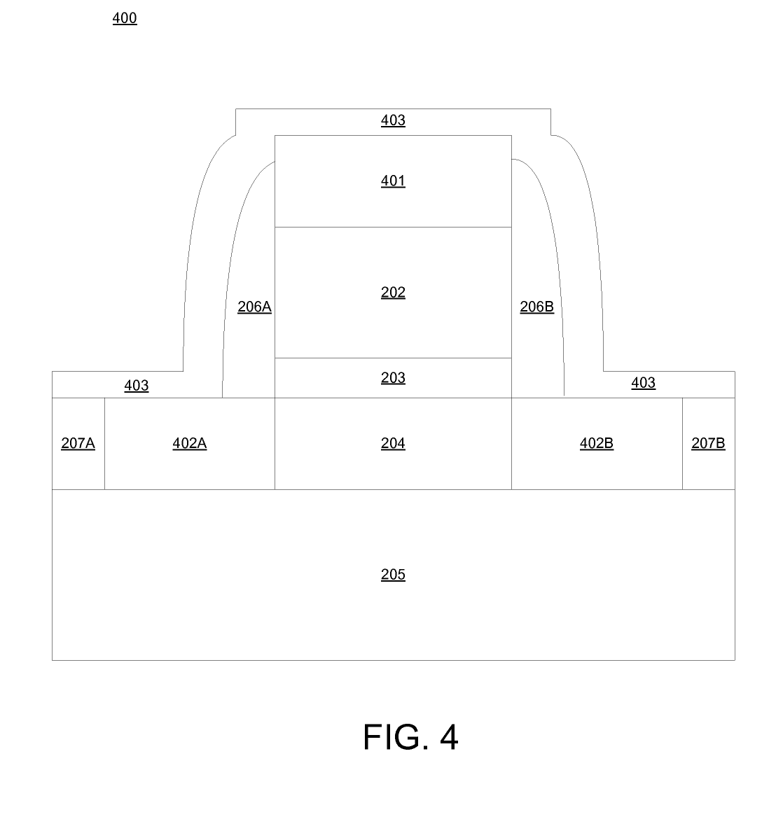

In block 103, device 300 of FIG. 3 is annealed, causing metal layer 301 to react with polysilicon layer 201 and silicon substrate 204. The anneal may comprise a relatively low-temperature anneal, at a temperature of about 350° C. or higher in some embodiments. The reaction between metal layer 301 and silicon regions 201 and 204 results in the simultaneous formation of gate silicide 401 and source/drain silicide 402A-B, covered by unreacted metal layer 403, as shown in FIG. 4. The material comprising spacers 206A-B may be selected such that spacers 206A-B do not react with metal layer 301. In embodiments in which the deposited metal layer 301 comprises Ni, the ratio of the thickness of polysilicon layer 201 to the thickness of the deposited Ni may be about 1.8 or lower to guarantee formation of a FUSI gate, converting all of polysilicon layer 201 into silicide 401. Therefore, if polysilicon layer 201 is about 18 nm thick, deposition of an Ni layer having a thickness of about 10 nm may result in a FUSI gate comprising a nickel silicon (NiSi) gate silicide 401 having a thickness of about 22 nm. Gate silicide 401 and source/drain silicide 402A-B may have approximately the same thickness.

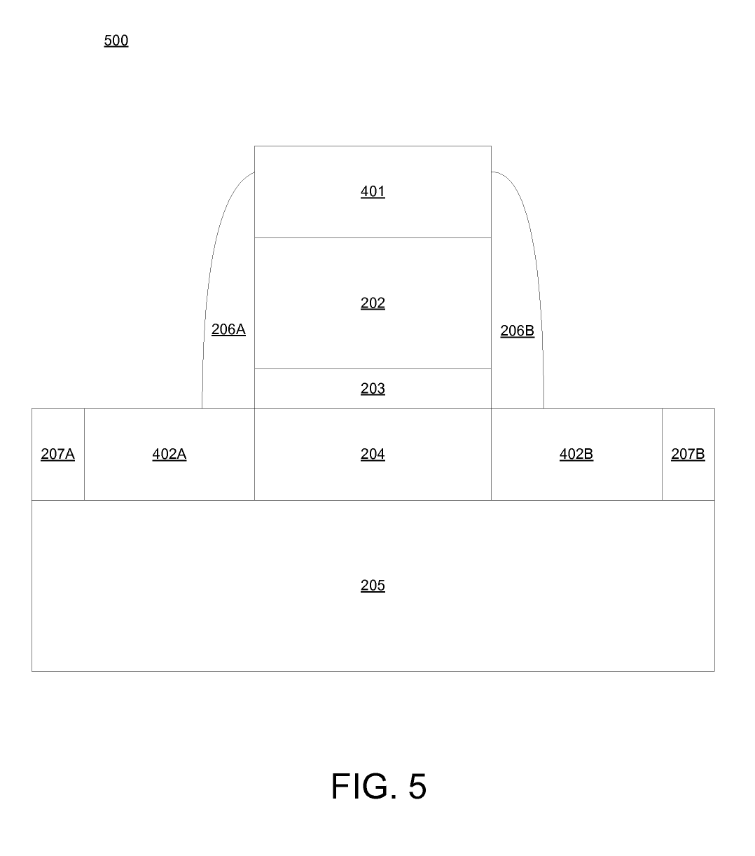

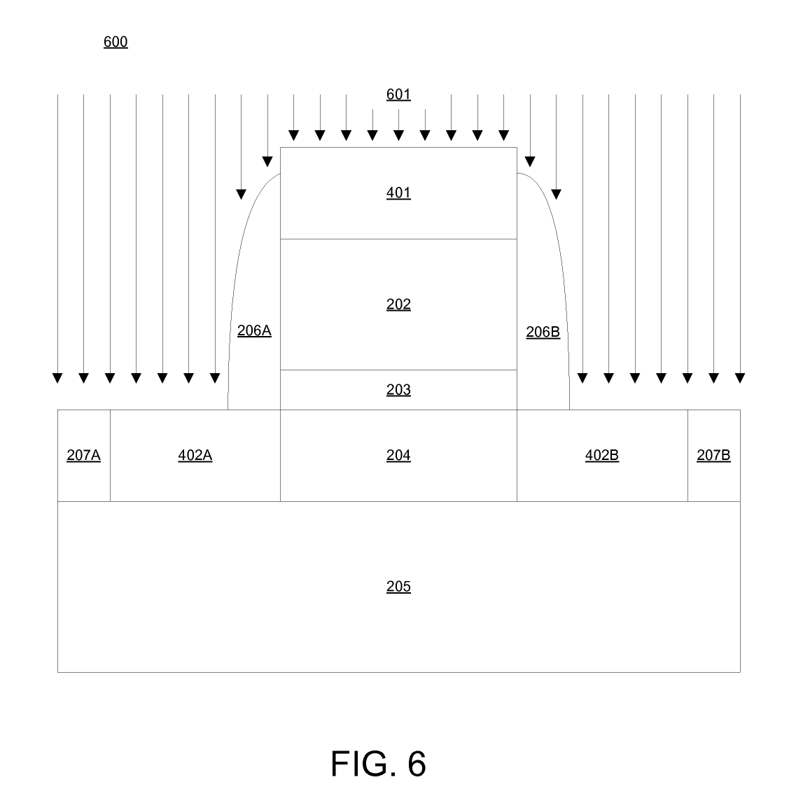

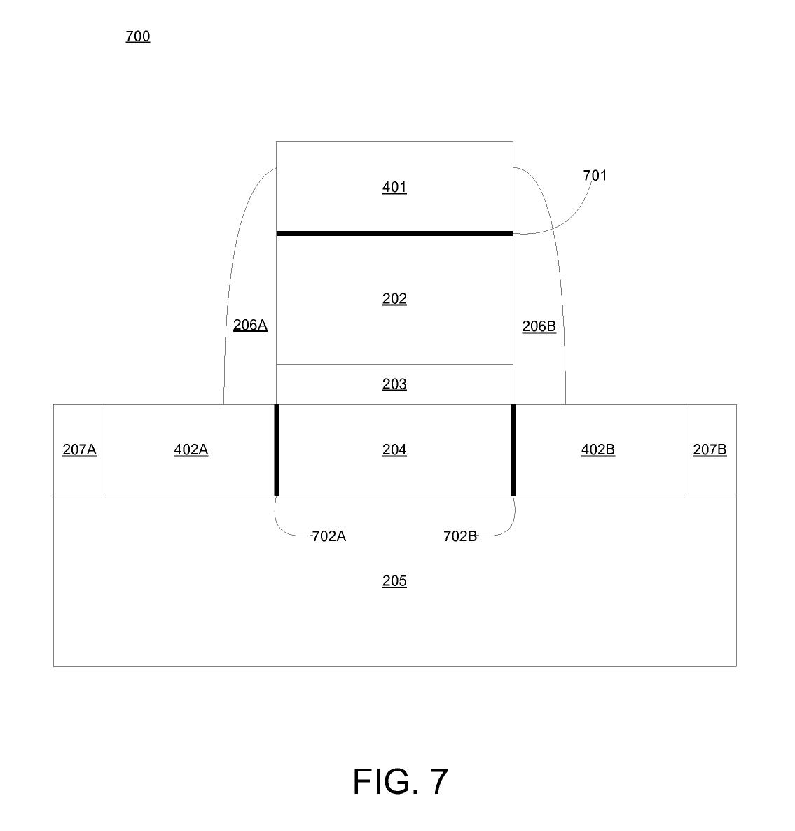

In block 104, the unreacted metal layer 403 is removed from gate silicide 401 and source/drain silicide 402A-B, as shown in FIG. 5. Gate silicide 401 and source/drain silicide 402A-B may have approximately the same thickness. In block 105, implantation 601 of dopants may be performed on gate silicide 401 and source drain silicide 402A-B, as shown in FIG. 6. Implantation 601 may comprise implantation of n-type dopants, including but not limited to arsenic or phosphorous, to form an n-FET, or p-type dopants, including but not limited to boron, indium, or aluminum, to form a p-FET. After implantation 601 is performed, low-temperature rapid thermal annealing (RTA) is performed on the implanted device 600 to diffuse the dopants to through gate silicide 401 and source/drain silicide 402A-B to gate interface layer 701 and source/drain interface layer 702A-B, forming Schottky FET 700 as shown in FIG. 7. Schottky FET 700 comprises an all metal gate, comprising gate silicide 401, gate interface layer 701, gate metal layer 202, and high-k material layer 203. Gate interface layer 701 is located between gate silicide 401 and gate metal layer 202, and source/drain interface layers 702A-B are located between source/drain silicide 402A-B and silicon substrate 204. Gate interface layer 701 is a segregated interfacial layer that acts set the gate workfunction for FET 700, and source/drain interface layers 702A-B are segregated interfacial layers that act to reduce the source/drain contact resistance of FET 700.

The technical effects and benefits of exemplary embodiments include a relatively low-temperature process for forming a Schottky FET having an all metal gate.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A method for forming a Schottky field effect transistor (FET), the method comprising:
forming a gate stack on a silicon substrate, the gate stack comprising a gate polysilicon on top of a gate metal layer;
depositing a metal layer over the gate polysilicon and the silicon substrate;
annealing the metal layer, the gate polysilicon, and the silicon substrate such that the metal layer fully consumes the gate polysilicon to form a gate silicide and reacts with portions of the silicon substrate to form source/drain silicide regions in the silicon substrate; and
in the event a portion of the metal layer does not react with the gate polysilicon or the silicon substrate, removing the unreacted portion of the metal layer.

2. The method of claim 1, wherein silicon substrate comprises silicon on insulator and has a thickness of about 10 nanometers or less, and a thickness of the gate polysilicon and the thickness of the silicon substrate are approximately the same.

3. The method of claim 1, wherein the gate stack further comprises a layer of a high-k material between the silicon substrate and the gate metal layer.

4. The method of claim 1, wherein the gate metal layer comprises one of titanium nitride and tantalum nitride.

5. The method of claim 1, wherein the gate metal layer has a thickness greater than about 10 nanometers.

6. The method of claim 1, wherein the annealing is performed at a temperature of above about 350° C.

7. The method of claim 1, wherein the gate silicide and the source/drain silicide regions are of approximately the same thickness.

8. The method of claim 1, wherein the metal layer comprises one of nickel (Ni) and nickel platinum (NiPt).

9. The method of claim 8, wherein the metal layer comprises Ni, and a ratio of a thickness of the gate polysilicon to a thickness of the metal layer is about 1.8 or less.

10. The method of claim 1, further comprising:
implanting the gate silicide and the source/drain silicide regions with dopants; and
performing low-temperature rapid thermal annealing (RTA) to diffuse the implanted dopants to a gate interface layer located between the gate silicide and the gate metal layer, and source/drain interface layers between the source/drain silicide regions and the silicon substrate.

11. The method of claim 1, further comprising forming at least one spacer on the silicon substrate adjacent to the gate metal layer and the gate polysilicon.

12. The method of claim 1, wherein the at least one spacer comprises a nitride, and has a thickness of 10 nanometers or less.

13. A Schottky field effect transistor (FET), comprising:
a silicon substrate;
source/drain silicide regions located in the silicon substrate;
a gate stack located on the silicon substrate, the gate stack comprising:
a high-k material layer located on the silicon substrate;
a gate metal layer located on the high-k material layer; and
a gate silicide located on the gate metal layer; and
a gate interface layer located between the gate silicide and the gate metal layer, and source/drain interface layers located between the source/drain silicide regions and the silicon substrate.

14. The Schottky FET of claim 13, wherein the source/drain silicide regions and the gate silicide comprise one of Ni and NiPt.

15. The Schottky FET of claim 13, wherein the gate metal layer has a thickness greater than about 10 nanometers.

16. The Schottky FET of claim 13, wherein the gate metal layer comprises one of titanium nitride or tantalum nitride.

17. The Schottky FET of claim 13, wherein the silicon substrate comprises silicon on insulator and has a thickness of about 10 nanometers or less, and wherein the thickness of the silicon substrate is approximately the same as a thickness of the gate silicide and a thickness of the source/drain silicide regions.

18. The Schottky FET of claim 13, further comprising at least one spacer adjacent located on the silicon substrate adjacent to the gate stack.

19. The Schottky FET of claim 18, wherein the at least one space comprises a nitride, and has a thickness of 10 nanometers or less.

20. The Schottky FET of claim 13, wherein the a gate interface layer and source/drain interface layers comprise segregated interfacial layers comprising one of arsenic, phosphorous, boron, indium, and aluminum.
